(19) United States
(12) Patent Application Publication
(10) Pub. No.: US 2007/0108609 A1
(43) Pub. Date: May 17, 2007

(54) Bumped chip carrier package using lead frame and method for manufacturing the same

(75) Inventors: In Ku Kang, Cheonan-city (KR); Sang Ho Ahn, Suwon-city (KR)

Correspondence Address: LEE & MORSE, P.C., 3141 FAIRVIEW PARK DRIVE, SUITE 500, FALLS CHURCH, VA, 22042, US

(73) Assignee: Samsung electronics Co., Ltd.

(21) Appl. No.: 11/518,491

(22) Filed: Sep. 11, 2006

Related U.S. Application Data
(63) Continuation-in-part of application No. 10/888,580, filed on Jul. 12, 2004, now Pat. No. 7,109,065.
Application No. 10/888,580 is a division of application No. 10/118,944, filed on Apr. 10, 2002, now Pat. No. 6,818,976.

(30) Foreign Application Priority Data
Jul. 19, 2001 (KR) 2001-43446

(51) Int. Cl. H01L 23/48; H01L 21/44

(52) U.S. Cl. 257/737; 438/613; 257/E23.021

(57) ABSTRACT

A bumped chip carrier (BCC) package may include a semiconductor chip on which at least one bonding pad is formed, at least one lead frame terminal arranged close to the semiconductor chip, wherein a lower portion of the lead frame terminal is located beneath a bottom side of the semiconductor chip, at least one bonding wire electrically connecting the bonding pad with the lead frame terminal, and a resin mold encapsulating the semiconductor chip, the bonding wire, and an upper portion of the lead frame terminal with a molding resin, wherein the upper portion of the lead frame terminal is electrically connected to the bonding pad by the bonding wire, and the lower portion of lead frame terminal extending beyond the resin mold has a dimple therein.

### CROSS-REFERENCE TO RELATED APPLICATIONS

present application is a continuation-in-part application of, and claims priority under 35 U.S.C. § 120 to U.S. patent application Ser. No. 10/888,580, filed on Jul. 12, 2004, and entitled “BUMPED CHIP CARRIER PACKAGE USING LEAD FRAME AND METHOD FOR MANUFACTURING THE SAME,” allowed, which is a divisional application of, and claims priority under 35 U.S.C. § 120 to, U.S. patent application Ser. No. 10/118,944, now U.S. Pat. No. 6,818,976, both of which are incorporated by reference in their entirety.

### BACKGROUND OF THE INVENTION

1. Field of the Invention

The present invention relates to a semiconductor package and a met hod for manufacturing the same. More particularly, the present invention relates to a bumped chip carrier package using a lead frame and a method for manufacturing the same.

2. Description of the Related Art

In an effort to reduce the size and weight of multi-function electronic devices while simultaneously increasing speed and performance, high-density integrated circuits (ICs) are being mounted in high-density packages. One such high-density package is a chip scale package (CSP), wherein ICs are mounted directly on a substrate. Although such CSPs have been manufactured in sizes as small as a single IC, a CSP may provide for the mounting of multiple ICs on a common substrate or carrier, such as a printed circuit board (PCB), a tape circuit board, or a lead frame. One such conventional CSP is a bumped chip carrier (BCC) package, which uses a lead frame as shown in FIGS. 1 through 3, wherein FIG. 2 illustrates a cross-sectional view taken along line 2-2 in FIG. 1.

Referring to the two views of the BCC package shown in FIGS. 1 and 2, a semiconductor chip 20 is attached to a chip mounting area 12 of a lead frame 10, and a plurality of contact grooves 14 are formed around the periphery of the chip mounting area 12. Each one of a plurality of bonding pads 24 on semiconductor chip 20 are electrically connected to an associated contact groove 14 by a bonding wire 30. The semiconductor chip 20, the plurality of bonding wires 30, and the plurality of contact grooves 14 on lead frame 10 are then encapsulated with a molding resin to form a resin mold 40.

Each contact groove 14 typically includes a depression having an overlaying plating layer 16, which is formed by successive deposition and/or etching of metal layers using metals, such as stannum (Sn), palladium (Pd), and aurum (Au). Since it is difficult to attach a bonding wire 30 directly to the concave plating layer 16, a conventional procedure for connecting the bonding wire 30 to the plating layer 16 is typically a two-step process.

In a first step, a first plurality of ball solder bumps 32 are formed on each one of the contact locations on plating layer 16 using a ball bonding technique. A second plurality of ball solder bumps are then formed on each one of the bonding pads 24 of semiconductor chip 20. A stitch bonding operation is then performed to connect each end of the bonding wires 30 to the associated ball solder bumps.

An alternate variation on this conventional CSP might feature the elimination of lead frame 10 under the resin mold 40 by using a selective etching, such as that shown by the conventional bumped chip carrier package 50 of FIG. 3. In bumped chip carrier package 50, an external contact terminal 18 has a structure in which plating layer 16 is filled with a molding resin.

Because the height of the external contact terminals 18 in the bumped chip carrier package 50 may be adjustably controlled during the manufacturing process of the lead frame, the bumped chip carrier package 50 has a significant advantage over conventional semiconductor chip mounting techniques using conventional solder balls as an external contact terminal.

Disadvantageously, however, since a conventional external contact terminal structure features a plating layer 16 being filled with a molding resin, plating layer 16 may exhibit cracking due to a difference in thermal expansion coefficients between the plating layer 16 and the molding resin during conventional manufacturing tests of bumped chip carrier package 50, for example, during a temperature cycling (T/C) test. Another significant disadvantage of conventional CSPs is that the aforementioned two-step ball bonding operation is typically required in the wire bonding process.

### SUMMARY OF THE INVENTION

The present invention is therefore directed to a bumped chip carrier (BCC) and method of manufacturing the same, which substantially overcome one or more of the problems due to the limitations and disadvantages of the related art.

It is therefore a feature of an embodiment of the present invention to provide a BCC package that is manufactured to use a lead frame capable of preventing damage to an external contact terminal during manufacturing testing.

It is another a feature of an embodiment of the present invention to provide a BCC package using a lead frame capable of electrically connecting a semiconductor chip and an internal contact terminal using a single wire bonding process.

It is yet another feature of an embodiment of the present invention to provide a BCC package having a strengthened solder joint.

At least one of the above and other features and advantages of the present invention may be realized by providing a method for manufacturing a bumped chip carrier package, the method including (a) providing a lead frame having a chip mounting area, a plurality of internal contact terminals protruding from the lead frame in an area beyond the chip mounting area on a first surface of the lead frame, and a plurality of dimples on a second surface, opposite the first surface, of the lead frame, the dimples corresponding to an associated one of the plurality of internal contact terminals, (b) attaching a semiconductor chip having a plurality of bonding pads to the chip mounting area, (c) electrically connecting each one of the plurality of bonding pads of the semiconductor chip to an associated one of the plurality of internal contact terminals using one of a plurality of bonding wires, (d) forming a resin mold by encapsulating the semiconductor chip, the plurality of bonding wires, and the plurality of internal contact terminals on the lead frame with a molding resin, and (e) forming a plurality of external contact terminals by removing the lead frame except for a portion under each one of the plurality of internal contact terminals, each external contact terminal including an associated dimple.

Step (a) may include (a1) providing a lead frame, (a2) forming a first photoresist pattern at a plurality of locations associated with the locations for formation of the plurality of internal contact terminals on the lead frame, (a3) forming the plurality of internal contact terminals by wet etching the lead frame outside the first photoresist pattern to a predetermined depth, and (a4) removing the first photoresist pattern.

The method may include stamping the plurality of dimples in the lead frame.

Step (e) may include (e1) forming a second photoresist pattern under the lead frame such that a plurality of openings are created, each one of the plurality of openings being located under one of the plurality of internal contact terminals, (e2) forming a plurality of solder plating layers, each one being formed in an associated one of the plurality of openings in the second photoresist pattern, (e3) removing the second photoresist pattern, (e4) removing the lead frame located outside of the plurality of solder plating layers by using the plurality of solder plating layers as masks, and (e5) forming the plurality of external contact terminals by re-flowing the plurality of solder plating layers, such that the lead frame under each one of the plurality of solder plating layers are covered with solder.

Each one of the plurality of openings in the second photoresist pattern is formed to a size sufficient to include at least one of the plurality of internal contact terminals. An upper portion of each internal contact terminal may be laminated with silver (Ag).

At least one of the above and other features and advantages of the present invention may be realized by providing a bumped chip carrier package, including a semiconductor chip on which at least one bonding pad is formed, at least one lead frame terminal arranged close to the semiconductor chip, wherein a lower portion of the lead frame terminal is located beneath a bottom side of the semiconductor chip, at least one bonding wire electrically connecting the bonding pad with the lead frame terminal, and a resin mold encapsulating the semiconductor chip, the bonding wire, and an upper portion of the lead frame terminal with a molding resin, wherein the upper portion of the lead frame terminal is electrically connected to the bonding pad by the bonding wire, and the lower portion of lead frame terminal extending beyond the resin mold has a dimple therein.

A middle portion of the internal contact terminal may have a constricted shape. A solder joint may cover the lower portion of the lead frame terminal, including the dimple. The lower portion of the lead frame terminal may be generally trapezoidal. The bottom side of the semiconductor chip may not be covered by the resin mold.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates a top view of a conventional lead frame having a bumped chip carrier package with an attached semiconductor chip;

FIG. 2 illustrates a cross-sectional view taken along line 2-2 in FIG. 1, showing a bumped chip carrier package having a resin mold;

FIG. 3 illustrates a cross-sectional view of a conventional bumped chip carrier package that is manufactured without a lead frame; and

FIGS. 4-15 illustrate a manufacturing process of a bumped chip carrier package using a lead frame according to an embodiment of the present invention, wherein:

FIG. 4 illustrates a top view of a first photoresist pattern that is formed on a lead frame;

FIG. 5 illustrates a cross-sectional view taken along line 5-5 in FIG. 4;

FIG. 6 illustrates a cross-sectional view of the lead frame after a first wet etching step;

FIG. 7 illustrates a cross-sectional view of a lead frame in which a plurality of internal contact terminals are formed by removing the first photoresist pattern of FIG. 4;

FIG. 8 illustrates a cross-sectional view of an attachment of a semiconductor chip to the lead frame;

FIG. 9 illustrates a cross-sectional view of an attachment of a plurality of bonding wires;

FIG. 10 illustrates a cross-sectional view of an encapsulation of the assembly using a resin mold;

FIG. 11 illustrates a cross-sectional view of a formation of a second photoresist pattern;

FIG. 12 illustrates a cross-sectional view of a formation of a solder plating layer;

FIG. 13 illustrates a cross-sectional view of a removal of the second photoresist pattern;

FIG. 14 illustrates a cross-sectional view of the lead frame after a second wet etching step; and

FIG. 15 illustrates a cross-sectional view of a formation of a plurality of external contact terminals using a solder re-flowing of a solder plating layer, resulting in a bumped chip carrier package in accordance with an embodiment of the present invention;

FIG. 16 illustrates a cross-sectional view of a bumped chip carrier package in accordance with another embodiment of the present invention; and

FIGS. 17A and 17B are comparisons of crack propagation in bumped chip carrier packages according to embodiments of the present invention.

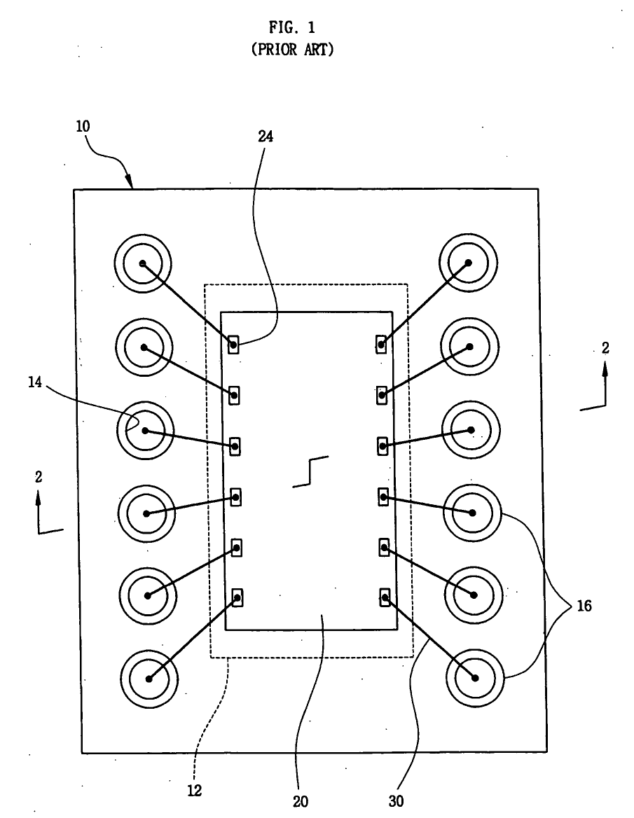

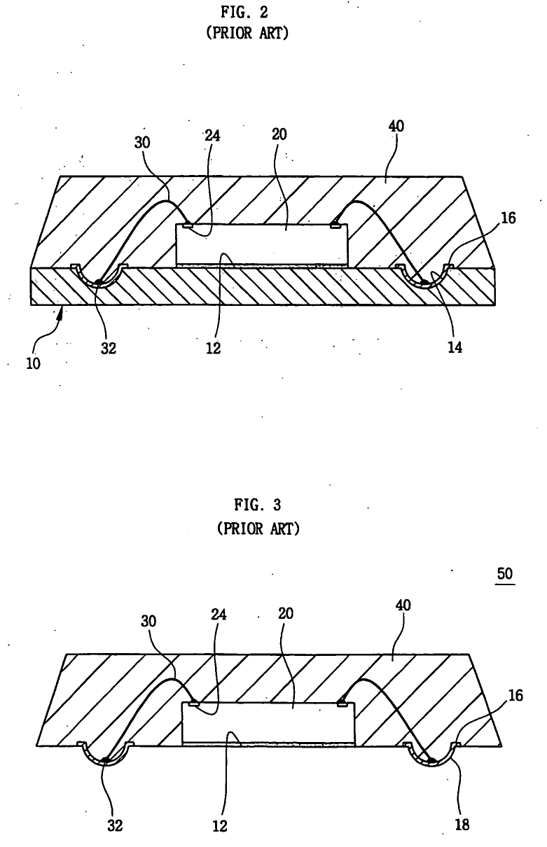

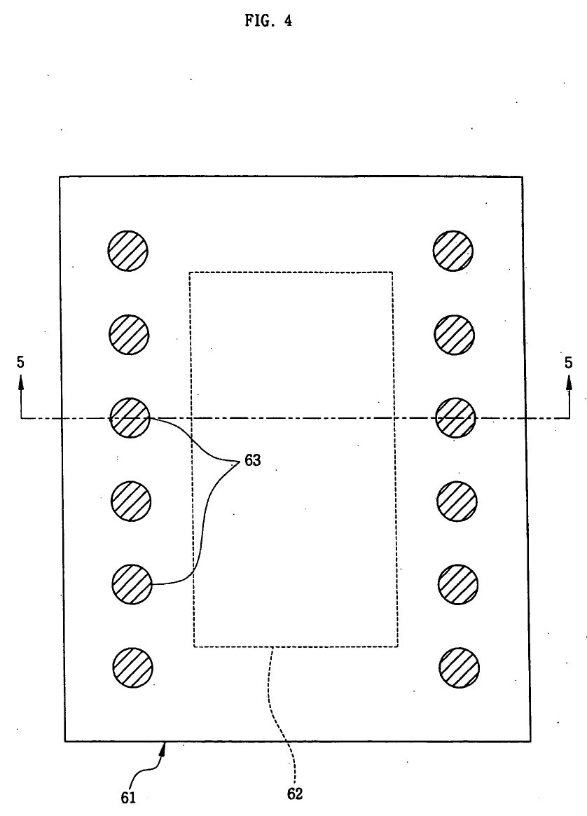

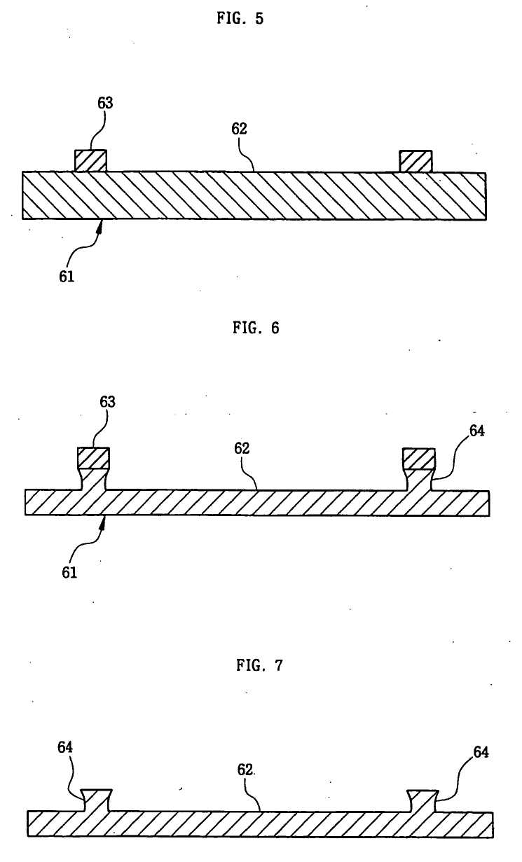

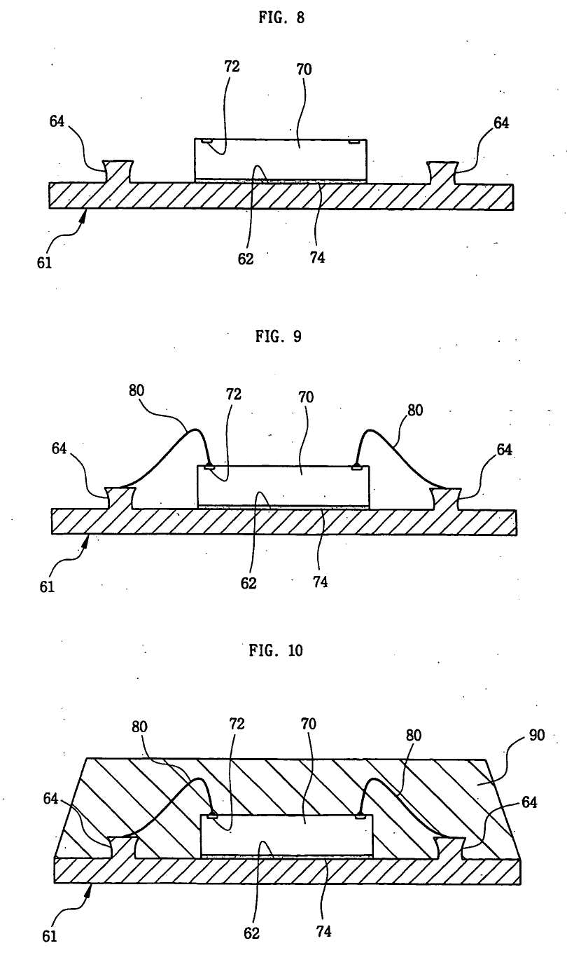

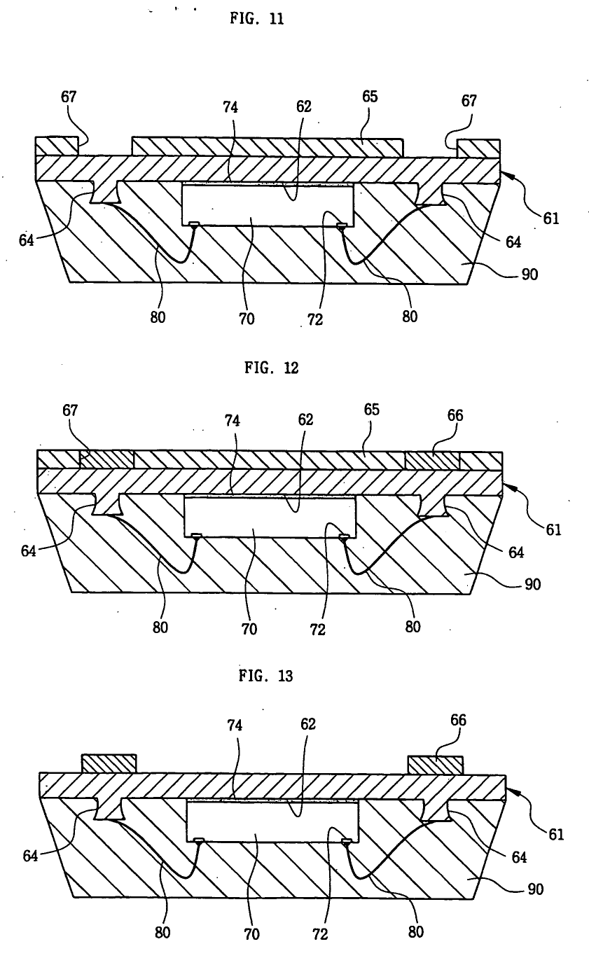

### DETAILED DESCRIPTION OF THE INVENTION

Korean Patent Application No. 2001-43446 filed on Jul. 19, 2001, and entitled “Bumped Chip Carrier Package Using Lead Frame and Method for Manufacturing The Same,” is incorporated by reference herein in its entirety.

The present invention will now be described more fully hereinafter with reference to the accompanying drawings, in which preferred embodiments of the invention are shown. This invention may, however, be modified in different forms and should not be construed as limited to the embodiments set forth herein. Rather, these embodiments are provided so that this disclosure will be thorough and complete, and will fully convey the scope of the invention to those of ordinary skill in the art. Like reference numbers refer to like elements throughout.

FIGS. 4 to 15 illustrate a cross-sectional view of the steps of a process for manufacturing a bumped chip carrier package having a lead frame 61 according to an embodiment of the present invention. Although only one lead frame 61 is shown in FIGS. 4 to 15, multiple lead frames may be manufactured simultaneously using a strip form of manufacturing in the application of the following steps.

FIGS. 4 and 5 illustrate a top view and a cross-sectional view taken along the line 5-5 in FIG. 4, respectively, of the lead frame 61, which is preferably made using an alloy of iron (Fe) or copper (Cu) and has a chip mounting area 62. Referring to FIGS. 4 and 5, in a first step, a first photoresist pattern 63 is formed on an upper side of lead frame 61. More specifically, a first photoresist material is deposited on the upper side of lead frame 61, and then a desired pattern is exposed/etched to form a plurality of contact terminals.

FIG. 6 illustrates a next stage, wherein a plurality of internal contact terminals 64 are formed by wet etching lead frame 61 outside of the photoresist pattern 63 to a predetermined depth. Herein, the photoresist pattern 63 is used as a mask. Since the internal contact terminals 64 are formed using a wet etching process, a middle portion of each internal contact terminal has a constricted shape.

FIG. 7 illustrates a next stage, wherein the first photoresist pattern 63 is removed to expose internal contact terminals 64. For improved wire bonding characteristics, an upper portion of each internal contact terminal 64 may be laminated with silver (Ag).

FIG. 8, a semiconductor chip 70 having bonding pads 72 is attached to chip mounting area 62 of the lead frame 60 preferably by using an adhesive layer 74, such as silver-epoxy adhesive, solder, and double-faced adhesive tape.

As shown in FIG. 9, a plurality of ball solder bumps are formed on each of the bonding pads 72 of semiconductor chip 70. Then, a stitch bonding operation is performed to connect each end of the bonding wires 80 to the associated internal contact terminal 64 of the lead frame 61.

FIG. 10 illustrates an encapsulation stage, wherein a resin mold 90 is preferably formed over the entire assembly. Preferably, resin mold 90 completely encapsulates semiconductor chip 70,. the plurality of bonding wires 80, and the plurality of internal contact terminals 64 on lead frame 61. A transfer molding method and/or potting method may be used to form resin mold 90. Since the middle portion of the internal contact terminal 64 has a constricted shape, resin mold 90 and lead frame 61 are more tightly bound together than if the internal contact terminal had a straight, columnar shape.

Hereinafter, an external contact terminal of the lead frame will be described with reference to FIGS. 11 through 15.

As shown in FIG. 11, a second photoresist pattern 65 is formed on an inverted lead frame 61 to a representative thickness of 10 82 m such that a portion of the internal contact terminal 64 is exposed. Preferably, openings 67 in the second photoresist pattern 65 are formed to a size that is larger than the associated internal contact terminal 64.

FIG. 12 illustrates a subsequent stage of forming a conductive solder plating layer 66 in each one of the openings 67. During the formation of solder plating layer 66, lead frame 61 may be used as a terminal for plating.

Next, as shown in FIG. 13, the second photoresist pattern 65 outside of solder plating layers 66 is removed. The remaining solder plating layers 66 are to be used as a mask during a subsequent etching process.

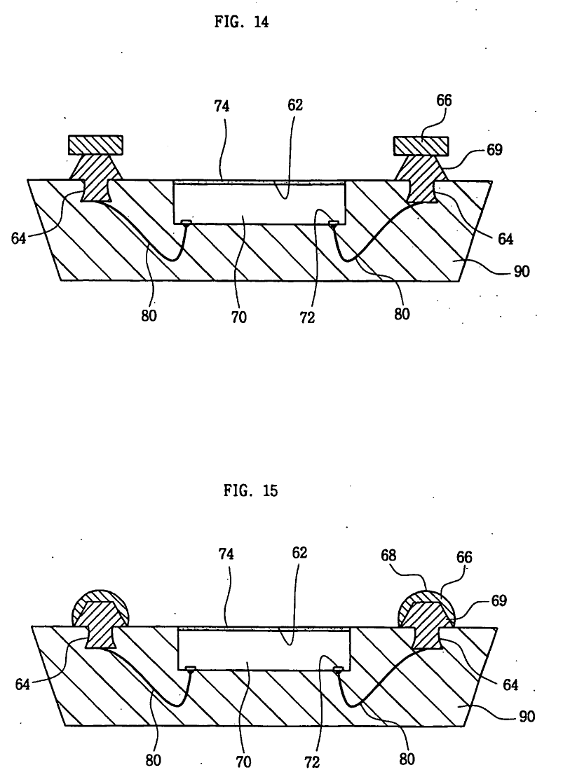

As shown in FIG. 14, the assembly is wet etched selectively using the areas of solder plating layer 66 as a mask to produce a trapezoidal-shaped protruding portion 69 under solder plating layer 66. The wet etch is performed to a sufficient depth to expose adhesive 74 and the original “bottom” side of the semiconductor chip 70, in order to provide an added benefit of a thermal path for externally dissipating any heat generated during the operation of the semiconductor chip 70.

In a final stage, as shown in FIG. 15, a plurality of external contact terminals 68 are formed by re-flowing solder plating layer 66 such that a hemispherical shaped solder cap is created that covers the trapezoidal-shaped protruding portions 69. The resulting solder covering the exterior of the external contact terminals 68 provides added reliability for connection with an external mounting board.

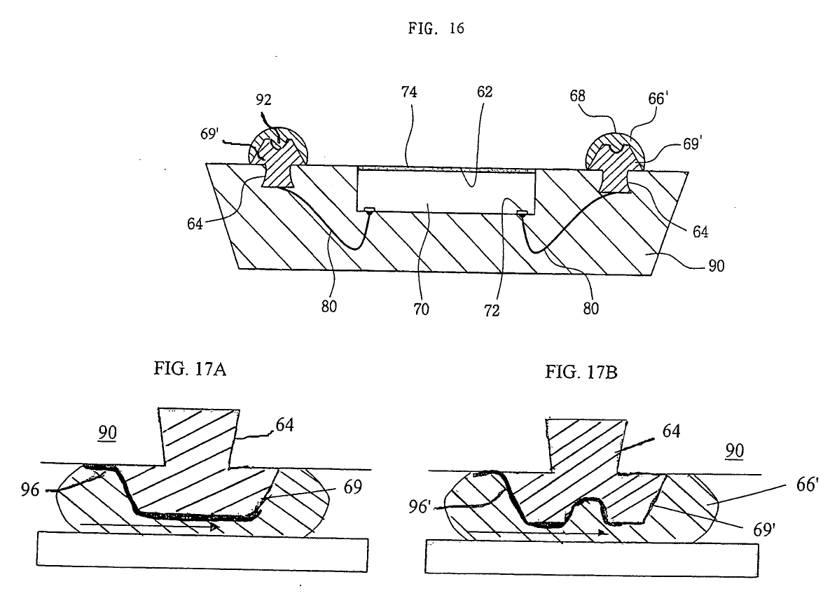

FIG. 16 illustrates a cross-sectional view of a bumped chip carrier package in accordance with another embodiment of the present invention. Only differences between this embodiment and the previous embodiment of FIG. 15 will be discussed, as the other elements and manufacturing steps remain the same.

As can be seen in FIG. 16, protruding portions 69′ may include a dimple 92 therein. By forming the dimple 92 on the protruding portion 69′, shear strength of a solder joint 66′ may be enhanced. In other words, the presence of the dimple may lengthen a propagation route of a crack, which may enhance the reliability of the solder joint 66′ as compared with the solder joint 66 of the previous embodiment.

FIG. 17A illustrates direction of propagation of a possible crack 96 in the-solder joint 66 of the bumped chip carrier package of FIG. 15, and FIG. 17B illustrates direction of propagation of a possible crack 96′ in the solder joint 66′ of the bumped chip carrier package of FIG. 16. As can be seen by comparing FIGS. 17A and 17B, the crack 96′ in the solder 66′ in FIG. 17B has to traverse a longer distance to result in separation from the protruding portion 69′ than does the crack 96 in the solder 66 in FIG. 17B to result in separation form the protruding portion 69.

A method for manufacturing the bumped chip carrier package of FIG. 16 may include an additional step of forming the dimple 92, e.g., before the solder plating layer is applied. The dimple 92 may be formed in any known manner, e.g., by stamping the lead frame 61 opposite where the internal contact terminal 64 is to be formed, e.g., after formation of the internal contact terminal 64 in FIG. 7.

According to embodiments of the present invention, damage to an external contact terminal may be prevented during manufacturing testing, such as temperature cycling (T/C), because a portion of the lead frame is used to form a frame for external contact terminals and portions of the lead frame that are exposed outside of the resin mold are covered with solder. Additionally, the present invention makes it possible to connect a semiconductor chip and an internal contact terminal by a single wire bonding process, rather than the two-step wire bonding process required in conventional manufacturing applications.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the invention as set forth in the following claims.

What is claimed is:

1. A method for manufacturing a bumped chip carrier package, the method comprising:
(a) providing a lead frame having a chip mounting area, a plurality of internal contact terminals protruding from the lead frame in an area beyond the chip mounting area on a first surface of the lead frame, and a plurality of dimples on a second surface, opposite the first surface, of the lead frame, the dimples corresponding to an associated one of the plurality of internal contact terminals;
(b) attaching a semiconductor chip having a plurality of bonding pads to the chip mounting area;
(c) electrically connecting each one of the plurality of bonding pads of the semiconductor chip to an associated one of the plurality of internal contact terminals using one of a plurality of bonding wires;
(d) forming a resin mold by encapsulating the semiconductor chip, the plurality of bonding wires, and the plurality of internal contact terminals on the lead frame with a molding resin; and
(e) forming a plurality of external contact terminals by removing the lead frame except for a portion under each one of the plurality of internal contact terminals, each external contact terminal including an associated dimple.

2. The method as claimed in claim 1, wherein (a) comprises:
(a1) providing a lead frame;
(a2) forming a first photoresist pattern at a plurality of locations associated with the locations for formation of the plurality of internal contact terminals on the lead frame;
(a3) forming the plurality of internal contact terminals by wet etching the lead frame outside the first photoresist pattern to a predetermined depth; and
(a4) removing the first photoresist pattern.

3. The method as claimed in 2, further comprising stamping the plurality of dimples in the lead frame.

4. The method as claimed in claim 1, wherein (e) comprises:
(e1) forming a second photoresist pattern under the lead frame such that a plurality of openings are created, each one of the plurality of openings being located under one of the plurality of internal contact terminals;
(e2) forming a plurality of solder plating layers, each one being formed in an associated one of the plurality of openings in the second photoresist pattern;
(e3) removing the second photoresist pattern;
(e4) removing the lead frame located outside of the plurality of solder plating layers by using the plurality of solder plating layers as masks; and
(e5) forming the plurality of external contact terminals by re-flowing the plurality of solder plating layers, such that the lead frame under each one of the plurality of solder plating layers are covered with solder.

5. The method as claimed in claim 4, wherein each one of the plurality of openings in the second photoresist pattern is formed to a size sufficient to include at least one of the plurality of internal contact terminals

6. The method as claimed in claim 1, wherein an upper portion of each internal contact terminal is laminated with silver (Ag).

7. A bumped chip carrier package, comprising:
a semiconductor chip on which at least one bonding pad is formed;
at least one lead frame terminal arranged close to the semiconductor chip, wherein a lower portion of the lead frame terminal is located beneath a bottom side of the semiconductor chip;
at least one bonding wire electrically connecting the bonding pad with the lead frame terminal; and
a resin mold encapsulating the semiconductor chip, the bonding wire, and an upper portion of the lead frame terminal with a molding resin,
wherein the upper portion of the lead frame terminal is electrically connected to the bonding pad by the bonding wire, and
the lower portion of lead frame terminal extending beyond the resin mold has a dimple therein.

8. The bumped chip carrier package as claimed in claim 7, wherein a middle portion of the internal contact terminal has a constricted shape.

9. The bumped chip carrier package as claimed in claim 7, further comprising a solder joint covering the lower portion of the lead frame terminal, including the dimple.

10. The bumped chip carrier package as claimed in claim 7, wherein the lower portion of the lead frame terminal is generally trapezoidal.

11. The bumped chip carrier package as claimed in claim 7, wherein the bottom side of the semiconductor chip is not covered by the resin mold.
